(19) United States
(12) Patent Application Publication
(10) Pub. No.: US 2014/0166107 A1
(43) Pub. Date: Jun. 19, 2014

(54) Back-Contact Electron Reflectors Enhancing Thin Film Solar Cell Efficiency

(71) Applicant: INTERMOLECULAR, INC., San Jose, CA (US)

(72) Inventors: Mankoo Lee, Fremont, CA (US); Sergey Barabash, San Jose, CA (US); Tony P. Chiang, Campbell, CA (US); Dipankar Pramanik, Saratoga, CA (US)

(73) Assignee: INTERMOLECULAR, INC., San Jose, CA (US)

(21) Appl. No.: 13/714,274

(22) Filed: Dec. 13, 2012

(51) Int. Cl. H01L 31/0264; H01L 31/18

(52) U.S. Cl. CPC H01L 31/0264; H01L 31/18
USPC 136/260; 136/252; 136/262; 136/264; 136/265; 438/72

(57) ABSTRACT

Methods for improving the efficiency of solar cells are disclosed. A solar cell consistent with the present disclosure includes a back contact metal layer disposed on a substrate. The solar cell also includes an electron reflector material(s) layer formed on the back contact metal layer and an absorber material(s) layer disposed on the electron reflector material(s) layer. In addition, the solar cell includes a buffer material(s) layer formed on the absorber material(s) layer wherein the electron reflector material(s) layer, absorber material(s) layer, and buffer material(s) layer form a pn junction within the solar cell. Furthermore, a TCO material(s) layer is formed on the buffer material(s) layer. In addition, the front contact layer is formed on the TCO material(s) layer.

### FIELD

The present disclosure relates to enhancing thin film solar cell efficiency.

### BACKGROUND

A conventional solar cell typically includes a light absorbing material(s) layer connected to an external circuit. Charge carriers are generated in the light absorber material(s) by absorbing photons of light therein which are subsequently driven towards one or more contacts within the cells. Advantageously, the charge establishes a photovoltage at open circuit (V_{oc}) and generates a photocurrent at short circuit. As such, when a load is connected to an external circuit, the solar cell can produce current and voltage to do electrical work.

Much research has been given to increasing the efficiency of solar cells. Solar cell efficiency is an important metric because it is an indirect measurement of the amount of power that can be generated from a solar cell. Two primary physical mechanisms have been considered to achieve high thin-film solar cell efficiency: (1) using p-type absorbers (e.g. Copper Indium Gallium Selenide also referred to as CIGS in addition to Cadium Telluride (i.e. CdTe) used in commercial photovoltaic products) to achieve maximum absorption of solar radiation and (2) attempting to maximize the carrier transport to each solar cell electrode (anode and cathode). Unfortunately, conventional approaches to each method have provided limited advances in solar cell efficiency.

In addition, other methods have been considered to improve solar cell efficiency: 1) reducing crystal or compound bulk defects in the absorber materials; 2) utilizing band-gap grading scheme(s) (e.g. backside grading in CIGS solar cell) in p-type absorber layer; and 3) properly utilizing pn hetero-junction interface layers to reduce carrier recombination effect (e.g. n-type inverted layer in CIGS solar) and/or transparent conductive oxide (TCO) layers to reduce non-uniformity effect (e.g. SnO₂:F in CdTe solar cell). Although these methods are currently being pursued to achieve higher thin film solar cell efficiencies, there are no clear solutions due to technology limitations in current research and design (R&D).

New methods to improve solar cell efficiency that include inserting reflector layers between the absorber materials and the back contact metal layer have shown promise. In particular, such methods include inserting optical reflectors into the solar cells to enhance back optical reflectance and quantum efficiency as possible back contact metal materials at the absorber backend. However, current methods of inserting optical reflectors within thin film solar cells may not be effective to fully provide continuous solar cell efficiency improvement. As such, an effective method to enhance solar cell efficiency is desired. The present disclosure addresses such a need.

### SUMMARY OF THE DISCLOSURE

The following summary is included in order to provide a basic understanding of some aspects and features of the present disclosure. This summary is not an extensive overview of the disclosure and as such it is not intended to particularly identify key or critical elements of the disclosure or to delineate the scope of the disclosure. Its sole purpose is to present some concepts of the disclosure in a simplified form as a prelude to the more detailed description that is presented below.

Methods for improving the efficiency of solar cells are disclosed. A solar cell consistent with the present disclosure includes a back contact metal layer disposed on a substrate. The solar cell also includes an electron reflector material(s) layer formed on the back contact metal layer and an absorber material(s) layer formed on the electron reflector material(s) layer. In addition, the solar cell includes a buffer material(s) layer formed on the absorber material(s) layer wherein the electron reflector material(s) layer, absorber material(s) layer, and buffer material(s) layer form a pn junction within the solar cell. Furthermore, a TCO material(s) layer is formed on the buffer material(s) layer. In addition, the front contact layer is formed on the TCO material(s) layer.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale. The techniques of the present disclosure may readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system.

FIG. 4 is a simplified schematic diagram illustrating a conventional solar cell and lists the typical material compositions of a CIGS thin film photovoltaic (TFPV) solar cell.

FIG. 5 is a simplified schematic diagram illustrating a conventional solar cell and lists the typical material compositions of a CdTe TFPV solar cell.

FIG. 6 is a simplified schematic diagram illustrating a solar cell having an electron reflector material(s) layer formed on the CIGS absorber material(s) layer and the back contact metal layer.

FIG. 7 is a simplified schematic diagram illustrating a solar cell having an electron reflector material(s) layer formed on the CdTe absorber material(s) layer and the back contact metal layer.

FIG. 8 is a simplified energy band diagram for a CIGS solar cell having an electron reflector material(s) therein.

FIG. 9 is a simplified J-V plot illustrating current density-voltage characteristics results from various simulations of a CIGS solar cell with and without electron reflector material(s) layer insertion.

FIG. 10 is a simplified schematic diagram illustrating a combinatorial PVD system according to some embodiments described herein.

FIG. 11 is a simplified schematic diagram illustrating a substrate that has been processed in a combinatorial manner.

FIG. 12 is a simplified schematic diagram illustrating another example of a substrate having a pattern of site-isolated regions.

FIG. 13 is a simplified schematic diagram illustrating a combinatorial wet processing system according to some embodiments described herein.

FIG. 14 is a simplified schematic diagram illustrating a method having a number of trajectories through a process sequence having both conventional and combinatorial processes to form a TFPV solar cell.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to some embodiments have not been described in detail to avoid unnecessarily obscuring the description.

Methods for improving the efficiency of solar cells are disclosed. A solar cell consistent with the present disclosure includes a back contact metal layer disposed on a substrate. The solar cell also includes an electron reflector material(s) layer formed on the back contact metal layer and an absorber material(s) layer formed on the electron reflector material(s) layer. In addition, the solar cell includes a buffer material(s) layer formed on the absorber material(s) layer wherein the electron reflector material(s) layer, absorber material(s) layer, and buffer material(s) layer form a pn junction within the solar cell. Furthermore, a TCO material(s) layer is formed on the buffer material(s) layer. In addition, the front contact layer is formed on the TCO material(s) layer.

It is to be understood that unless otherwise indicated this disclosure is not limited to specific layer compositions or surface treatments. It is also to be understood that the terminology used herein is for the purpose of describing particular embodiments only and is not intended to limit the scope of the present disclosure.

It must be noted that as used herein and in the claims, the singular forms “a,” and “the” include plural referents unless the context clearly dictates otherwise. Thus, for example, reference to “a layer” also includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the disclosure. The upper and lower limits of these smaller ranges may independently be included in the smaller ranges, and are also encompassed within the disclosure, subject to any specifically excluded limit in the stated range. Where the stated range includes one or both of the limits, ranges excluding either or both of those included limits are also included in the disclosure. The term “about” generally refers to ±10% of a stated value.

The term “site-isolated” as used herein refers to providing distinct processing conditions, such as controlled temperature, flow rates, chamber pressure, processing time, plasma composition, and plasma energies. Site isolation may provide complete isolation between regions or relative isolation between regions. Preferably, the relative isolation is sufficient to provide a control over processing conditions within ±10%, within ±5%, within ±2%, within ±1%, or within ±0.1% of the target conditions. Where one region is processed at a time, adjacent regions are generally protected from any exposure that would alter the substrate surface in a measurable way.

The term “site-isolated region” as used herein refers to a localized area on a substrate which is, was, or is intended to be used for processing or formation of a selected material. The region may include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, coated silicon, other semiconductor materials, glass, polymers, metal foils, etc. The term “substrate” or “wafer” may be used interchangeably herein. Semiconductor wafer shapes and sizes may vary and include commonly used round wafers of 2″, 4″, 200 mm, or 300 mm in diameter.

The term “GIGS” as used herein may refer to the entire range of related alloys denoted by Cu(InₓGa₁₋ₓ)(S_{y}Se_{2-y}) where 0≦x≦1 and 0≦y≦2.

It is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration,” on a single substrate without the need of consuming the equivalent number of monolithic substrates per material(s), processing condition(s), sequence(s) of processing conditions, sequence(s) of processes, and combinations thereof. This may greatly improve both the speed and reduce the costs associated with the discovery, implementation, optimization, and qualification of material(s), process(es), and process integration sequence(s) required for manufacturing.

Systems and methods for HPC™ processing are described in U.S. Pat. No. 7,544,574 filed on Feb. 10, 2006; U.S. Pat. No. 7,824,935 filed on Jul. 2, 2008; U.S. Pat. No. 7,871,928 filed on May 4, 2009; U.S. Pat. No. 7,902,063 filed on Feb. 10, 2006; and U.S. Pat. No. 7,947,531 filed on Aug. 28, 2009 which are all herein incorporated by reference for all purposes.

Systems and methods for HPC™ processing are further described in U.S. patent application Ser. No. 11/352,077 filed on Feb. 10, 2006, claiming priority from Oct. 15, 2005; U.S. patent application Ser. No. 11/419,174 filed on May 18, 2006, claiming priority from Oct. 15, 2005; U.S. patent application Ser. No. 11/674,132 filed on Feb. 12, 2007, claiming priority from Oct. 15, 2005; U.S. patent application Ser. No. 13/204,827 filed on Sep. 12, 2011, and U.S. patent application Ser. No. 11/674,137 filed on Feb. 12, 2007, claiming priority from Oct. 15, 2005 which are all herein incorporated by reference for all purposes.

HPC™ processing techniques have been successfully adapted to wet chemical processing such as etching, texturing, polishing, cleaning, etc. HPC™ processing techniques have also been successfully adapted to deposition processes such as physical vapor deposition (PVD) (i.e. sputtering), atomic layer deposition (ALD), and chemical vapor deposition (CVD).

In addition, systems and methods for combinatorial processing are further described in U.S. patent application Ser. No. 13/341,993 filed on Dec. 31, 2011 and U.S. patent application Ser. No. 13/302,730 filed on Nov. 22, 2011 which are all herein incorporated by reference for all purposes.

HPC™ processing techniques have been adapted to the development and investigation of absorber layers and buffer layers for TFPV solar cells as described in U.S. patent application Ser. No. 13/236,430 filed on Sep. 19, 2011, entitled “COMBINATORIAL METHODS FOR DEVELOPING SUPERSTRATE THIN FILM SOLAR CELLS” and is incorporated herein by reference for all purposes.

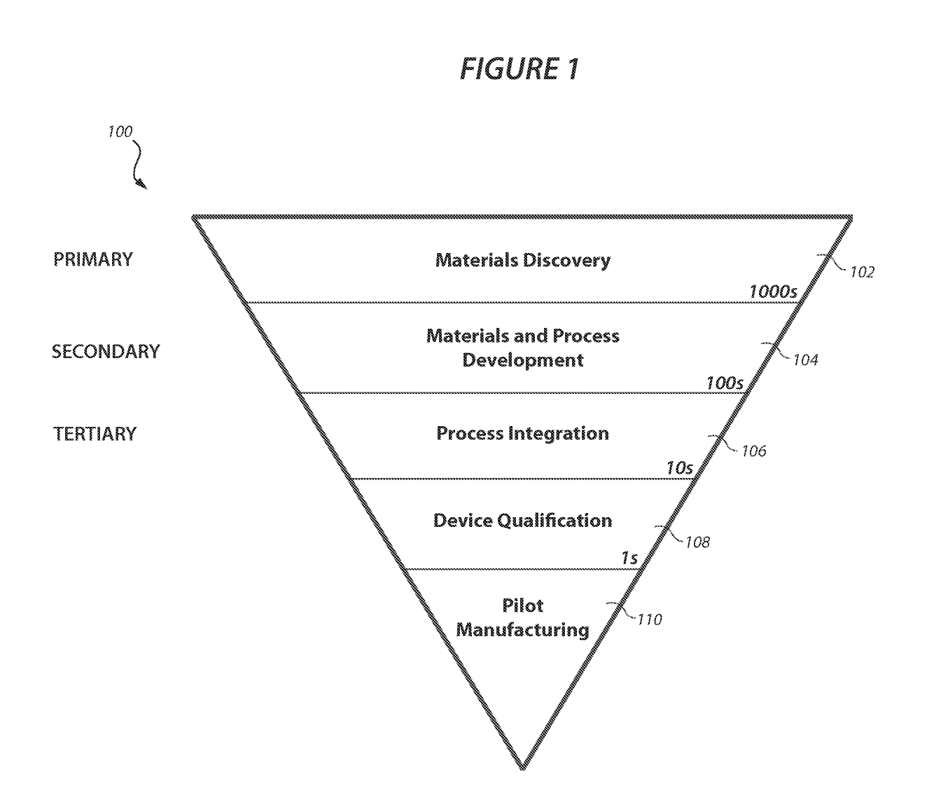

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages may be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (i.e. microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106 where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes may proceed to pilot manufacturing 110.

The schematic diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways.

This application benefits from HPC™ techniques described in U.S. patent application Ser. No. 11/674,137 filed on Feb. 12, 2007 which is hereby incorporated for reference for all purposes. Portions of the '137 application have been reproduced below to enhance the understanding of the present disclosure.

While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete site-isolated region. Furthermore, while different materials or unit processes may be used for corresponding layers or steps in the formation of a structure in different site-isolated regions of the substrate during the combinatorial processing, the application of each layer or use of a given unit process is substantially consistent or uniform throughout the different site-isolated regions in which it is intentionally applied. Thus, the processing is uniform within a site-isolated region (inter-region uniformity) and between site-isolated regions (intra-region uniformity), as desired. It should be noted that the process may be varied between site-isolated regions, for example, where a thickness of a layer is varied or a material may be varied between the site-isolated regions, etc., as desired by the design of the experiment.

The result is a series of site-isolated regions on the substrate that contain structures or unit process sequences that have been uniformly applied within that site-isolated region and, as applicable, across different site-isolated regions. This process uniformity allows comparison of the properties within and across the different site-isolated regions such that the variations in test results are due to the varied parameter (e.g., materials, unit processes, unit process parameters, hardware details, or process sequences) and not the lack of process uniformity. In the embodiments described herein, the positions of the discrete site-isolated regions on the substrate may be defined as needed, but are preferably systematized for ease of tooling and design of experimentation. In addition, the number, variants and location of structures within each site-isolated region are designed to enable valid statistical analysis of the test results within each site-isolated region and across site-isolated regions to be performed.

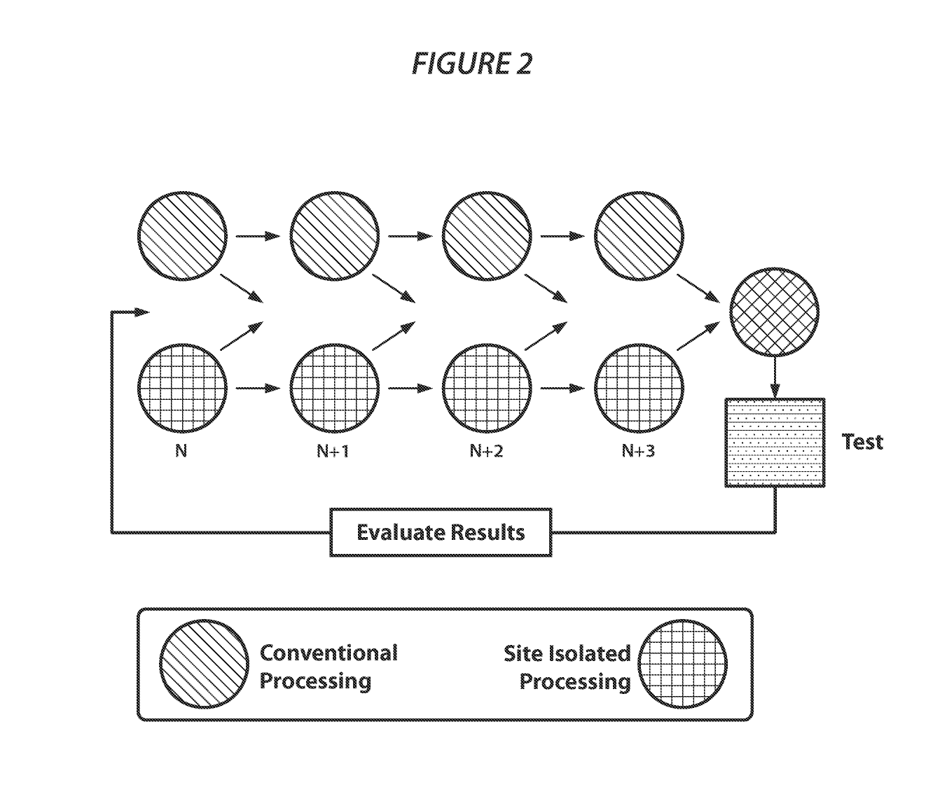

FIG. 2 is a simplified schematic diagram illustrating a general methodology for combinatorial process sequence integration that includes site-isolated processing and/or conventional processing. In some embodiments, the substrate is initially processed using conventional process N. In some exemplary embodiments, the substrate is then processed using site-isolated process N+1. During site-isolated processing, an HPC™ module may be used, such as the HPC module described in U.S. patent application Ser. No. 11/352,077 filed on Feb. 10, 2006, which is incorporated herein by reference for all purposes. The substrate may then be processed using site-isolated process N+2, and thereafter processed using conventional process N+3. Testing is performed and the results are evaluated. The testing may include physical, chemical, acoustic, magnetic, electrical, optical, etc. tests. From this evaluation, a particular process from the various site-isolated processes (e.g. from steps N+1 and N+2) may be selected and fixed so that additional combinatorial process sequence integration may be performed using site isolated processing for either process N or N+3. For example, a next process sequence may include processing the substrate using site isolated process N, conventional processing for processes N+1, N+2, and N+3, with testing performed thereafter.

It should be appreciated that various other combinations of conventional and combinatorial processes may be included in the processing sequence with regard to FIG. 2. That is, the combinatorial process sequence integration may be applied to any desired segments and/or portions of an overall process flow. Characterization, including physical, chemical, acoustic, magnetic, electrical, optical, etc. testing, may be performed after each process operation, and/or series of process operations within the process flow as desired. The feedback provided by the testing is used to select certain materials, processes, process conditions, and process sequences and eliminate others. Furthermore, the above flows may be applied to entire monolithic substrates, or portions of monolithic substrates such as coupons.

Under combinatorial processing operations the processing conditions at different site-isolated regions may be controlled independently. Consequently, process material amounts, reactant species, processing temperatures, processing times, processing pressures, processing flow rates, processing powers, processing reactant compositions, the rates at which the reactions are quenched, deposition order of process materials, process sequence steps, hardware details, etc., may be varied from site-isolated region to site-isolated region on the substrate. Thus, for example, when exploring materials, a processing material delivered to a first and second site-isolated region may be the same or different. If the processing material delivered to the first site-isolated region is the same as the processing material delivered to the second isolated-region, this processing material may be offered to the first and second site-isolated regions on the substrate at different concentrations. In addition, the material may be deposited under different processing parameters. Parameters which may be varied include, but are not limited to, process material amounts, reactant species, processing temperatures, processing times, processing pressures, processing flow rates, processing powers, processing reactant compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used may be varied.

As mentioned above, within a site-isolated region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the site-isolated regions. It should be appreciated that a site-isolated region may be formed on another site-isolated region in some embodiments or the site-isolated regions may be isolated and, therefore, non-overlapping. When the site-isolated regions are adjacent, there may be a slight overlap wherein the materials or precise process interactions are not known, however, a portion of the site-isolated regions, normally at least 50% or more of the area, is uniform and all testing occurs within that site-isolated region. Further, the potential overlap is only allowed with material of processes that will not adversely affect the result of the tests. Both types of site-isolated regions are referred to herein as site-isolated regions or discrete site-isolated regions.

Substrates may be a conventional round 200 mm, 300 mm, or any other larger or smaller substrate/wafer size. In some embodiments, substrates may be square, rectangular, or any other shape. One skilled in the art will appreciate that substrate may be a blanket substrate, a coupon (e.g., partial wafer), or even a patterned substrate having predefined site-isolated regions. In some other embodiments, a substrate may have site-isolated regions defined through the processing described herein.

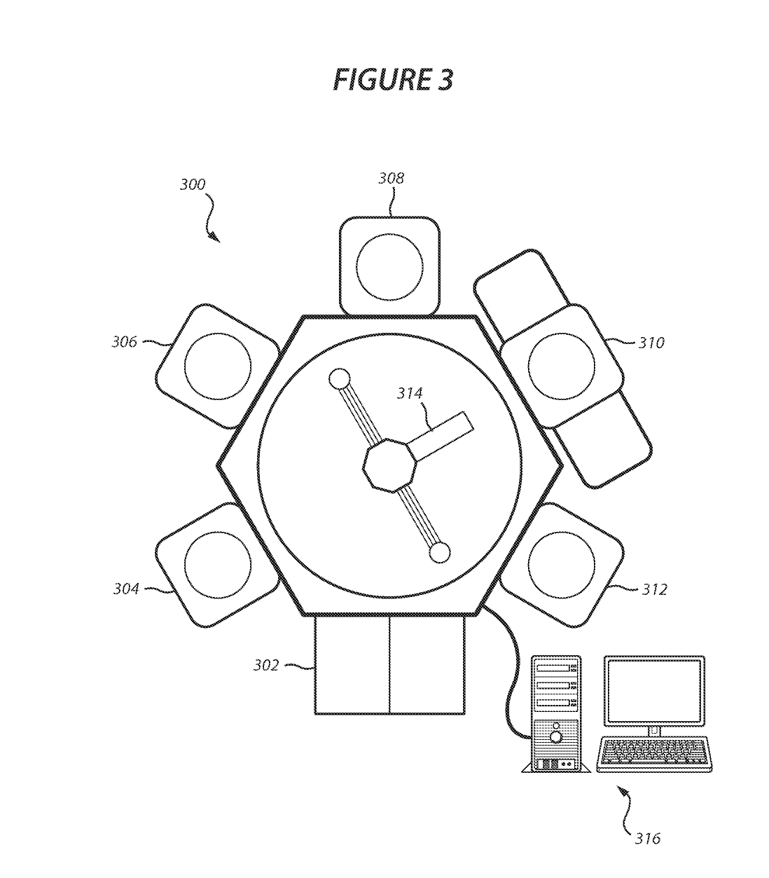

FIG. 3 is a simplified schematic diagram illustrating HPC system. The HPC system includes a frame 300 supporting a plurality of processing modules. It will be appreciated that frame 300 may be a unitary frame in accordance with some embodiments. In some embodiments, the environment within frame 300 is controlled. A load lock 302 provides access into the plurality of modules of the HPC system. A robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that may be supported to combine combinatorial processing or combinatorial plus conventional processing of a substrate or wafer. In some embodiments, a centralized controller, i.e., computing device 316, may control the processes of the HPC system. Further details of one possible HPC system are described in U.S. patent application Ser. Nos. 11/672,473 and 11/672,478, the entire disclosures of which are herein incorporated by reference for all purposes. In a HPC system, a plurality of methods may be employed to deposit material upon a substrate employing combinatorial processes.

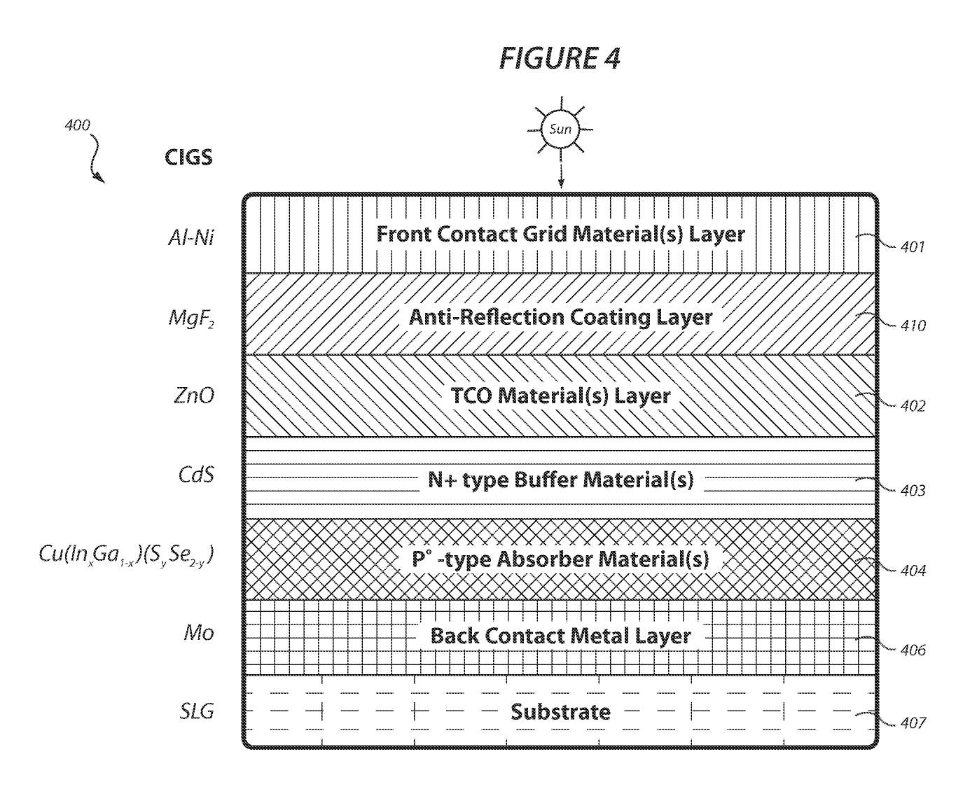

FIG. 4 is a simplified schematic diagram illustrating a conventional solar cell 400 and lists the typical material compositions of CIGS TFPV solar cell. The convention will be used wherein light is assumed to be incident upon the top of the material stack 400 as illustrated.

As shown, CIGS TFPV solar cells include a back contact metal layer 406 (e.g. Mo) formed on a substrate 407 (e.g. SLG). In some embodiments, the thickness of back contact metal layer 406 may have a thickness between approximately 0.3 μm and 0.8 μm. Furthermore, the back contact metal layer 406 may be formed using a PVD process or an evaporation process.

In some embodiments, CIGS absorber material(s) layer 404 is disposed on back contact metal layer 406. In some embodiments, the CIGS absorber material(s) layer 404 has a thickness between approximately 0.5 μm and 3.0 μm. The CIGS absorber material(s) layer 404 may be formed using any of a variety of techniques such as PVD, co-evaporation, printing or spraying inks, CVD, etc. Advantageously, the CIGS absorber material(s) layer 404 may be copper deficient. In some embodiments, the copper deficiency may be controlled by managing the deposition conditions.

Further, advantageously, a small amount of sodium may be contained in the CIGS absorber material(s) layer 404. In some embodiments, sodium may be added to the CIGS absorber material(s) layer 404 by an out-diffusion process from the substrate 407 or may be purposely added in the form of Na₂Se after the deposition of the CIGS absorber material(s) layer 404.

Furthermore, CIGS TFPV material stack 400 includes a buffer material(s) layer 403 (e.g. CdS) disposed on CIGS absorber material(s) layer 404. In some embodiments, the buffer material(s) layer 403 may have a thickness between approximately 30 nm and 80 nm. In addition, buffer material(s) layer 403 may be formed using a PVD technique.

Additionally, a low resistivity TCO material(s) layer 402 may be disposed on buffer material(s) layer 403. In some embodiments, suitable TCO material(s) may include any of Al:ZnO (AZO), InSnO (ITO), InZnO, B:ZnO, Ga:ZnO, F:ZnO, or F:SnO₂. In some embodiments, the TCO material(s) layer 402 may have a thickness between approximately 0.3 μm and 2.0 μm. The TCO layer 402 may be formed using a reactive PVD technique or CVD technique.

In addition, an intrinsic ZnO (iZnO) layer (not shown) may also be disposed on the buffer material(s) layer 403. In some embodiments, the iZnO layer is a high resistivity material and forms part of the TCO stack that serves as part of the front contact structure. In some embodiments, the iZnO layer makes the TFPV solar cell less sensitive to lateral non-uniformities that may be caused by differences in composition or defect concentration in the absorber or buffer material(s) layers.

The iZnO layer may have a thickness between approximately 30 nm and 80 nm. Additionally, the iZnO layer may be formed using a reactive PVD technique or CVD technique.

In addition, an optional anti-reflection coating (ARC) layer 410 (e.g. MgF₂) may be formed on top of the top TCO material(s) layer 402. In some embodiments, an ARC layer 410 may be formed on an iZnO layer. The ARC layer 410 increases the efficiency of the TFPV solar cell by reducing the reflection of the incident sunlight. Furthermore, in some embodiments, contained within the ARC layer 410 is an opaque metal grid (e.g. Al or Ni:Al) which has a thickness between approximately 0.5 μm and 2.0 μm.

In some embodiments, when the ARC layer 410 includes an opaque metal grid, the TCO material(s) layer 402 may be formed from materials which collect charge across the face of the TFPV solar cell. The collected charge conducts on the opaque metal grid which connects the solar cell 400 to external loads.

In some embodiments, solar cell 400 includes a front contact (grid) material(s) layer 401 disposed over the TCO materials layer 402. In some embodiments, front contact layer 401 is disposed on intrinsic ZnO layer. In some embodiments, front contact layer 401 is disposed on ARC layer 410 when an intrinsic ZnO layer is not included within the TFPV material(s) stack.

Suitable materials for front contact layer 401 may include aluminum, nickel, or a composite thereof. In some embodiments, front contact layer 401 may include any material that is conductive and substantially transparent to light in the visible spectrum. Typically, reactive PVD is a preferred method of deposition for front contact layer 401. In some embodiments, the thickness of front contact layer 401 may be between approximately 500 nm and 800 nm.

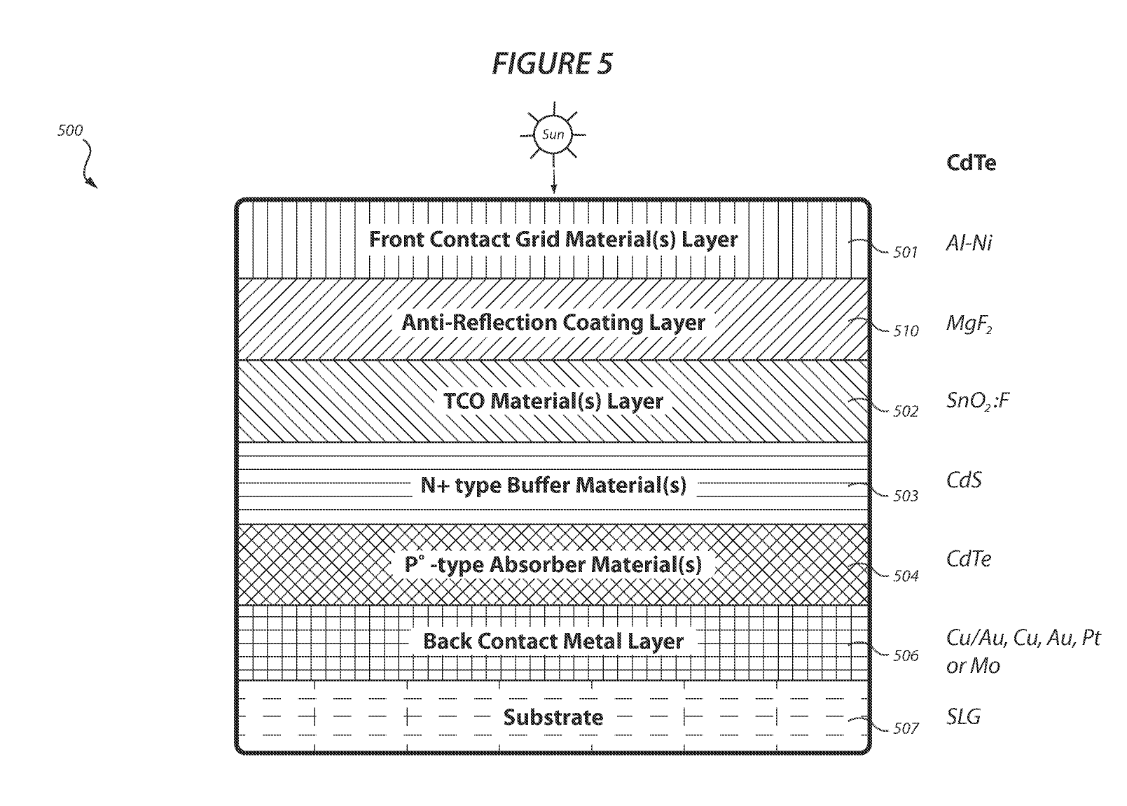

FIG. 5 is a simplified schematic diagram illustrating a conventional solar cell and lists the typical material compositions of a CdTe TFPV solar cell 500. As shown, CdTe solar cell 500 includes a back contact metal layer 506 disposed on a substrate 507. Typically, substrate 507 includes SLG or clear polymer(s). In some embodiments, the back contact metal layer 506 may be formed from several layers.

In addition, an absorber material(s) layer 504 may be disposed on the back contact metal layer 506. Examples of suitable back contact metal layer 506 include platinum and gold. In some embodiments, the back contact metal layer 500 can be directly contacted to the high doping p-type back surface of absorber material(s) layer 504 for realizing an electron reflector.

PVD may be a preferred method of deposition for the back contact metal layer 506. The thickness of the back contact metal layer 506 may be between approximately 300 nm and about 500 nm. The performance of the back contact metal layer 506 may be sensitive to material properties such as crystallinity, grain size, surface roughness, composition, and defect concentration in addition to process parameters (e.g. temperature, deposition rate, thermal treatments, etc.).

Moving forward, CdTe solar cell 500 includes a CdTe absorber material(s) layer (p-type) 504 disposed on back contact metal layer 506. The CdTe absorber material(s) layer 504 may be formed using any of a variety of techniques such as PVD, co-evaporation, printing or spraying inks, or CVD. In some embodiments, PVD is a preferred method of deposition for the CdTe absorber material(s) layer 504. The thickness of the CdTe absorber material(s) layer 504 may be between approximately 1.5 μm and about 3.0 μm. The performance of the CdTe absorber material(s) layer may be sensitive to material properties such as crystallinity, grain size, surface roughness, composition, and defect concentration in addition to processing parameters (e.g. temperature, deposition rate, thermal treatments, etc.).

Additionally, buffer material(s) layer 503 is disposed on the CdTe absorber material(s) layer 504. Examples of suitable n-type buffer material(s) layer 503 include CdS, ZnS, CdZnS, etc. In some embodiments, the buffer material(s) layer 503 may be deposited using chemical bath deposition (CBD), PVD, or evaporation and in some embodiments the thickness of the buffer material(s) layer is approximately 50 nm. The performance of the buffer material(s) layer 503 may be sensitive to material properties such as crystallinity, grain size, surface roughness, composition, and defect concentration in addition to process parameters (e.g. temperature, deposition rate, thermal treatments, etc.).

Furthermore, a TCO material(s) layer 502 may be disposed on top of a buffer material(s) layer 503. In some embodiments, the TCO material(s) layer 502 may have a thickness between approximately 0.3 μm and 2.0 μm.

In addition, an optional anti-reflection coating (ARC) layer 510 (e.g. MgF₂) may be formed on top of the top TCO material(s) layer 502 according to some embodiments. The optional ARC layer 510 increases the efficiency of the TFPV solar cell by reducing the reflection of the incident sunlight.

Finally, a CdTe solar cell 500 includes a front contact layer 501 which may be disposed on the TCO material(s) layer 502. In some embodiments, front contact layer 501 may be disposed on the optional ARC layer 510.

Suitable materials for front contact layer 501 may include aluminum, nickel, or a composite thereof. In some embodiments, front contact layer 501 may include any material that is conductive and substantially transparent to light in the visible spectrum. Typically, reactive PVD is a preferred method of deposition for front contact layer 501 and in some embodiments the thickness of front contact layer 501 may be between approximately 500 nm and 800 nm.

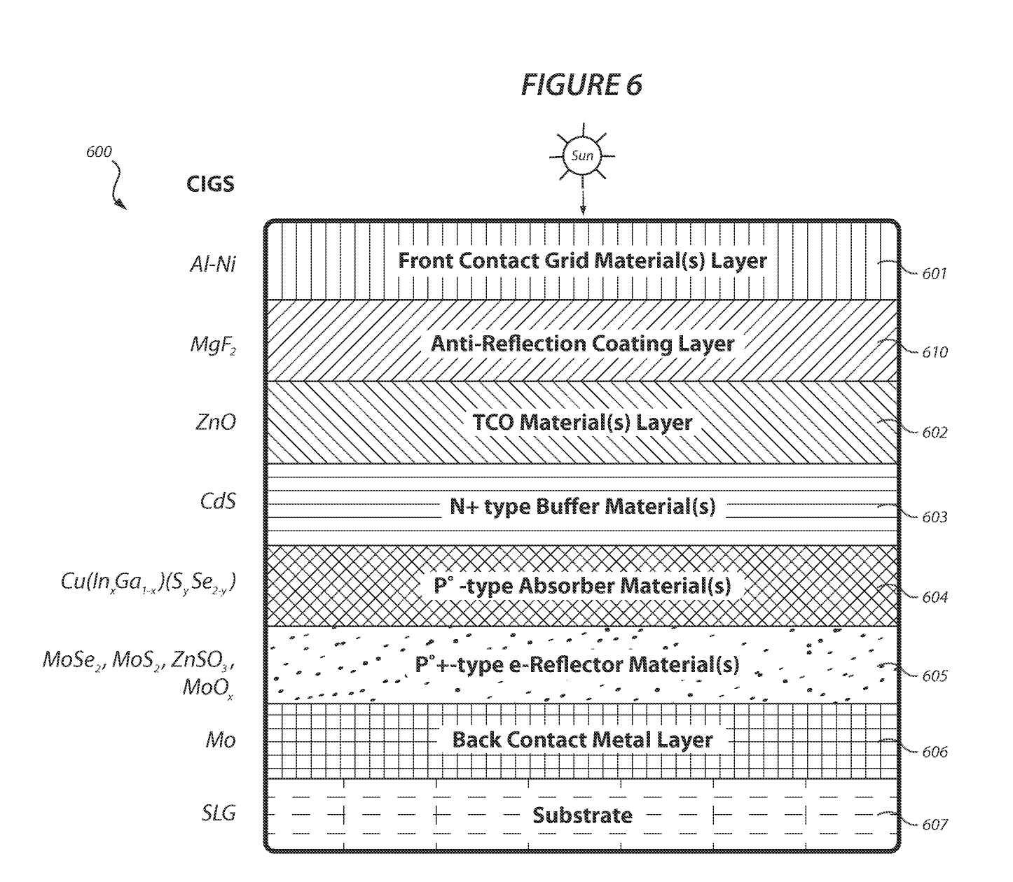

FIG. 6 is a simplified schematic diagram illustrating a solar cell 600 having an electron reflector material(s) layer 605 disposed on a CIGS absorber material(s) layer 604 and a back contact metal layer 606. In addition, the CIGS solar cell TFPV stack 600 comprises front contact grid material(s) layer 601, TCO material(s) layer 602, ARC layer 610, buffer material(s) layer 603, absorber material(s) layer 604, and back contact metal layer 606 all disposed on a substrate 607.

In some embodiments, CIGS absorber material(s) layer 604 may undergo a selenization process after formation. In some embodiments, the selenization process may involve exposing the CIGS absorber material(s) layer 604 to H₂Se, Se vapor, diethylselenide (DESe), or any combinations thereof at temperatures between about 400° C. and 600° C. During selenization, an electron reflector material(s) layer 605, such as MoSe₂, may form a good ohmic contact at the back contact-absorber material(s) interface. Other exemplary electron reflector material(s) for a CIGS TFPV solar cell are as follows: MoS₂, ZnSnO₃, and MoOₓ.

In some embodiments, the electron reflector material(s) layer 605 can serve dual roles within the solar cell 600. For instance, the electron reflector material(s) layer 605 can function as a conduction band energy (E_{c}) barrier (e.g. E_{c} offset) for residual minority carriers (e.g. electrons in p-type absorber material(s) layer) that stray into the region near the electron reflector material(s) layer. In some embodiments, the minority carriers in this area will be redirected by the electron reflector material(s) layer 605 towards the front contact layer 601 thereby promoting high solar cell efficiency. As such, in some embodiments, it is advantageous for the electron reflector material(s) layer 605 to have a wide band gap.

In addition, the electron reflector material(s) layer 605 should also promote or not hinder majority carrier transport (e.g. holes for p-type absorber material(s) layer) in the valence band (Eᵥ). In some embodiments, the electron reflector material(s) layer 605 promotes majority carrier transport by forming an ohmic Schottky contact with the back contact metal layer 606 at the valence band (e.g. MoSe₂—Mo back contact for a CIGS solar cell) such that a thin tunneling barrier is formed thereby promoting majority carrier transport.

In particular, the Schottky barrier microscopic dipole correction factor can affect new Ev band (valence band) offsets from the electron reflector material(s) layer 605 inserted between the absorber material(s) layer 604 and back metal contact layer 606. The Schottky barrier microscopic dipole correction factor can account for non-ideal charge transfer between the electron reflector material(s) layer 605 charge neutrality level and the back contact metal layer 606 fermi energy level (E_{f}) in Schottky barrier formation. It should be noted that a thin-film cell normally operates with typical ohmic contact with a certain barrier height at the back-side metal interface when the electron reflector material(s) layer 605 is not inserted. In particular, the electron reflector material(s) layer 605 electron reflector material(s) layer 605 forms a quasi-ohmic Schottky contact with the back metal contact layer 606 through a thin tunneling barrier at the valence band (e.g. MoSe₂—Mo back contact for CIGS solar cell case).

In some embodiments, the electron reflector material(s) layer 605 should have the same doping type (e.g. p-type) as the adjacent absorber material(s) layer 604. Most notably, the electron reflector material(s) layer 605 preferably has a wide band gap (E_{g}) within the range of 1.3≦E_{g}≦1.7 electron volts. For example, a CIGS solar cell 600 may have an electron reflector material(s) layer 605 with energy band gap height of approximately 1.4 eV for a MoSe₂ electron reflector material(s) layer.

It should be understood by one having ordinary skill in the art that the electron reflector material(s) layer integration may be material specific and may depend on various process factors such as but not limited to Eᵥ offset, dipole effects, and differences in material work functions.

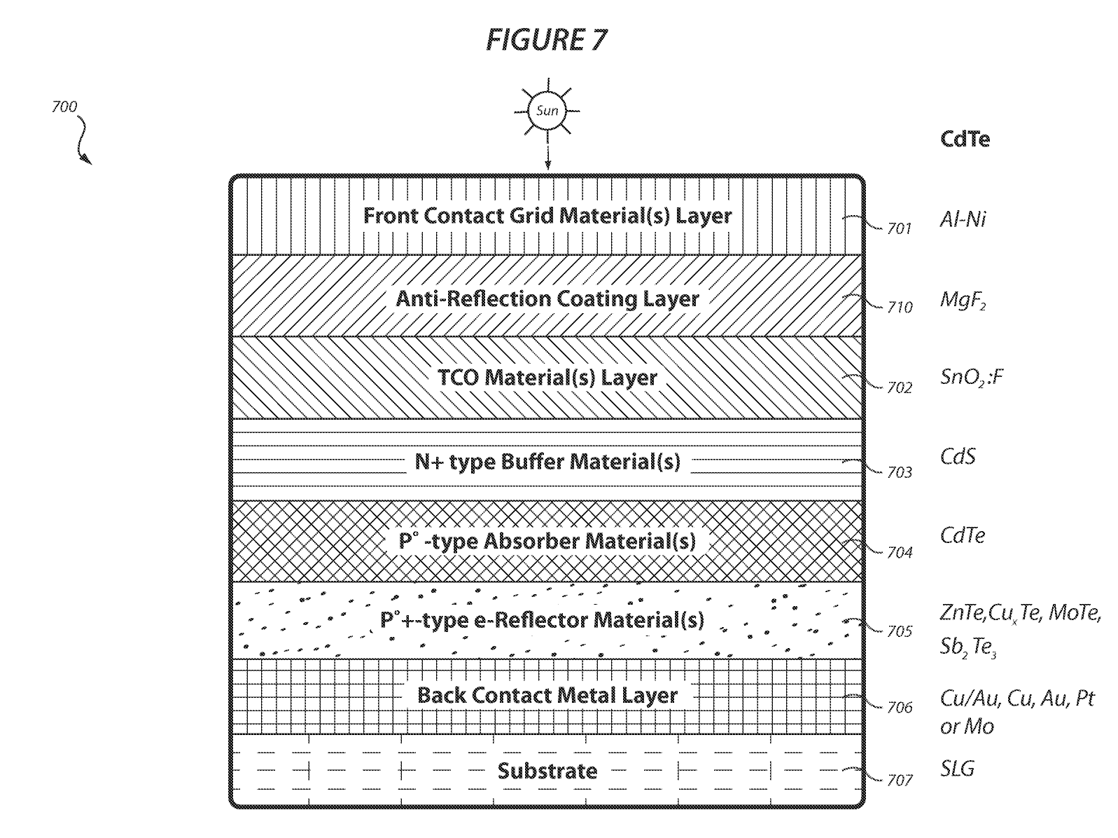

FIG. 7 is a simplified schematic diagram illustrating a solar cell 700 having an electron reflector material(s) layer 705 disposed on the CdTe absorber material(s) layer 704 and the back contact metal layer 706. It should be understood by one having ordinary skill in the art that solar cell 700 illustrated may have a similar configuration and function as the solar cell 600 illustrated in FIG. 6. However, the material composition of the solar cell 700 illustrated in FIG. 7, particularly each region or layer (front contact 701, ARC 710, TCO material(s) 702, buffer material(s) layer 703, absorber material(s) layer 704, electron reflector material(s) layer 705, back contact metal layer 706) is different as shown. Most notably, the electron reflector material(s) layer 705 may be any of the following compositions: ZnTe, CuₓTe, MoTe, Sb₂Te₃, and Cd₁₋ₓ(Znₓ, Mnₓ, Mgₓ)Te.

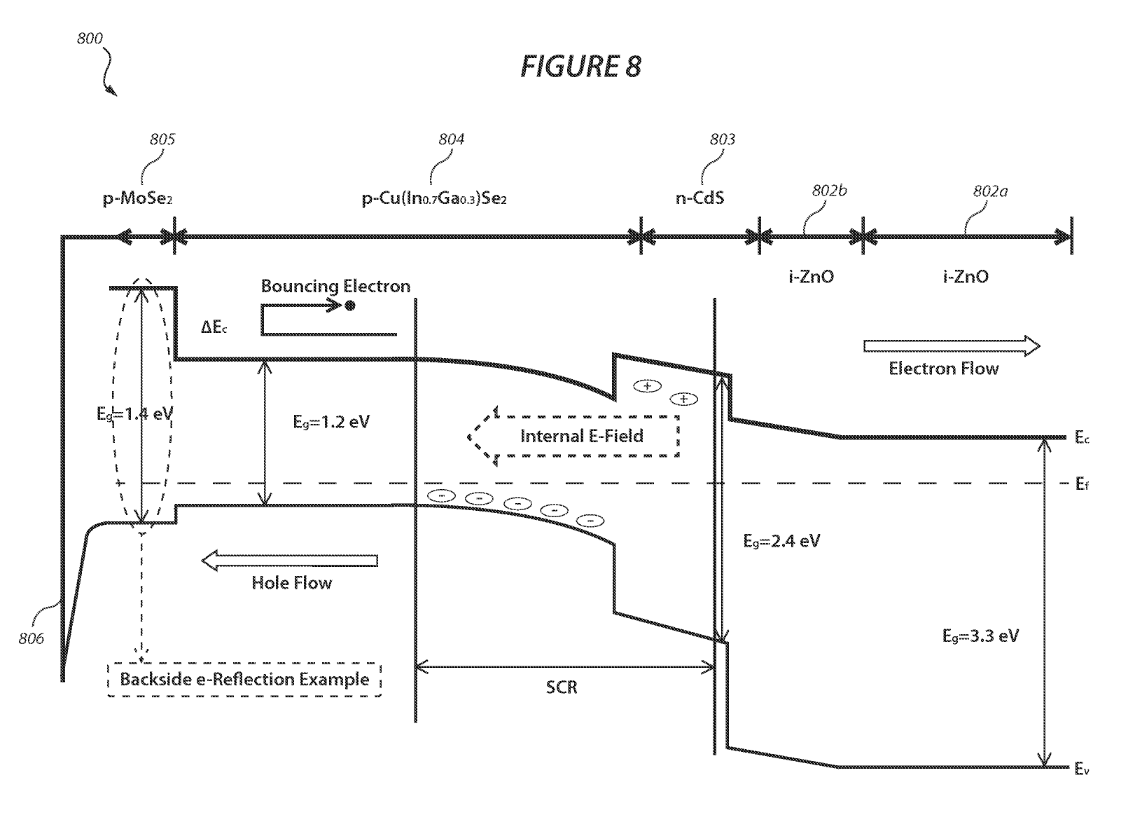

FIG. 8 is a simplified energy band diagram 800 or a CIGS solar cell having an electron reflector material(s) region 805 therein. As shown, the energy band diagram 800 illustrates different regions of the CIGS solar cell corresponding to layers within the solar cell.

Most notably, the energy band diagram 800 shows the E_{c} offset between absorber material(s) region 804 and electron reflector material(s) region 805. In some embodiments, as shown in energy band diagram 800, the E_{c} offset is approximately 0.2 eV. In some embodiments, the E_{c} offset between the absorber material(s) region 804 and the electron reflector material(s) region 805 may be in the range of 0.2-0.5 eV. Accordingly, when minority carriers (e.g. electrons) stray into the absorber material(s) region 804 and come into contact with the E_{c} offset, the minority carriers are redirected in the opposite direction towards the front contact layer (not shown).

Ideally, the minority carriers (e.g. electrons for p-type absorber material(s) region) travel with high velocities towards the front contact electrode (cathode), due to an internal electric field induced by a lightly-doped absorber material(s) layer. In some embodiments, the absorber material(s) region is fully depleted. In the event residual electrons stray towards the back contact metal layer, it is essential to redirect them back towards the front contact layer by the electron reflectors material(s) layer to maximize minority carrier transport.

In some embodiments, electron reflector material(s) layer may function as a quantum well. Also, the presence of the E_{c} offset can prevent possible surface recombination and thereby maximize the reflected electron transport rate towards the front contact electrode (not shown) and increase solar cell efficiency.

In some embodiments, the electron reflector material(s) region becomes more effective for a lightly-doped (e.g. ≦1E18 cm⁻³ acceptor concentration) and thin absorber material(s) region 804 and an electron reflector material(s) region 805 under near zero bias condition (or short circuit condition). In some embodiments, the aforementioned conditions create an internal electric field which can effectively sweep stray minority carriers towards the front contact layer (e.g. cathode).

Therefore, to maximize minority carrier transport to the front contact region, during near zero to V_{oc} forward bias operation, minority carriers can be effectively redirected by the E_{c} offset. Physically, the electron reflector material(s) region 805 may be considered a quantum well barrier at the conduction band (E_{c}) which allows electrons to bounce back towards the front contact region yielding a higher V_{oc} or J_{sce}.

Finally, the electron reflector material(s) region promotes majority carrier transport by forming an ohmic Schottky contact with the back contact metal such that a thin, tunneling barrier 806 is formed.

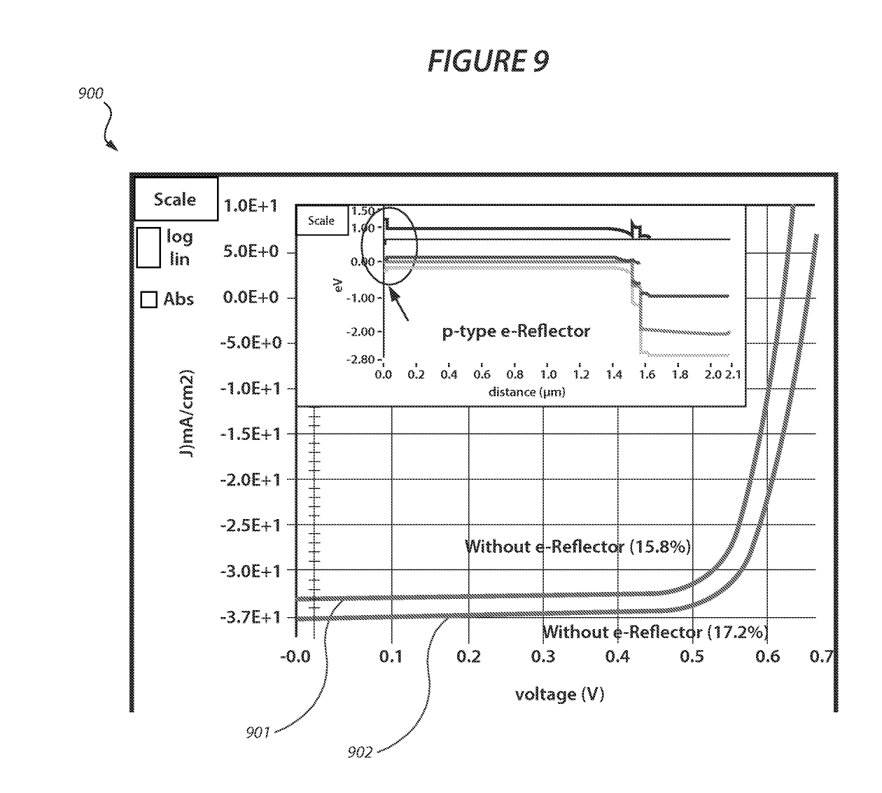

FIG. 9 is a simplified J-V plot 900 illustrating current density-voltage characteristics results from various simulations of a CIGS solar cell with and without electron reflector material(s) layer insertion. Particularly, the CIGS TFPV solar cell used in the simulation included an electron reflector material(s) layer with the following characteristics: ˜0.2 eV E_{c} offset at electron material(s) layer/absorber material(s) layer interface, a thickness of approximately 20 nm, and an acceptor concentration of 1E18 cm⁻³.

As shown, the insertion of an electron reflector material(s) layer (i.e. p-type MoSe₂) improves the J_{sce} without any aids from grading scheme(s). Most notably, as indicated by curves 901, 902, the simulation results yield approximately 1.4% improvement in solar cell efficiency after electron reflector material(s) layer insertion. It should be understood that methods consistent with the present disclosure have yielded upwards of 2% improvement in solar cell efficiency.

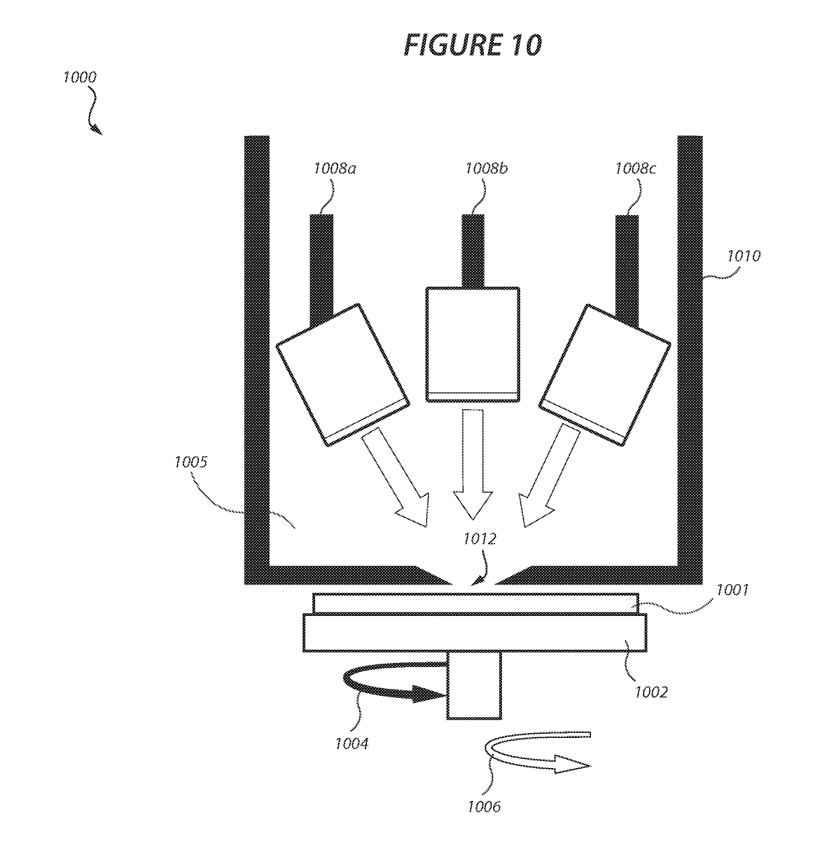

FIG. 10 is a simplified schematic diagram illustrating a combinatorial PVD system 1000 according to some embodiments described herein. Details of the combinatorial PVD system 1000 shown are described in U.S. patent application Ser. No. 12/027,980 filed on Feb. 7, 2008 claiming priority to U.S. patent application Ser. No. 12/028,643 filed on Feb. 8, 2008 claiming priority to Sep. 5, 2007 which are all herein incorporated by reference for all purposes.

As shown, a substrate 1001 is disposed on a substrate support 1002. In some embodiments, substrate support 1002 has two axes of rotation, 1004, 1006. In some embodiments, the two axes of rotation 1004, 1006 are not aligned which allows different regions on the substrate 1001 to be accessed for processing. In addition, the substrate support 1002 may be moved in a vertical direction to alter the spacing between the PVD targets and the substrate 1001.

In some embodiments, the combinatorial PVD system 1000 comprises multiple PVD assemblies 1008a-1008c configured within a PVD chamber 1005. In the figure, three PVD assemblies 1008a-1008c are present within the PVD chamber 1005. One having ordinary skill in the art will appreciate that any number of PVD assemblies 1008a-1008c within the PVD chambers 1005 may be used and that the number of assemblies is limited only by the size of the chamber 1005 and each PVD assembly 1008a-1008c.

Advantageously, each PVD assembly 1008a-1008c may contain an unique target material 1003a-1003c to allow a wide range of material and alloys compositions to be deposited and eventually investigated.

Additionally, the combinatorial PVD system 1000 may include the capability to perform reactive sputtering utilizing reactive gases such as O₂, NH₃, N₂, etc. The PVD assemblies 1008a-1008c may be moved in a vertical direction to alter the spacing between the PVD targets 1003a-1003c and the substrate 1001. In addition, the PVD assemblies 1008a-1008c may be further operable to tilt to alter an angle of incidence of sputtered material arriving at the surface of the substrate 1001.

Furthermore, the combinatorial PVD system 1000 comprises a process kit shield assembly 1010 which may include an aperture 1012 used to define site-isolated regions on the substrate 1001. In some embodiments, the portion of the process kit shield assembly 1010 that includes the aperture 1012 may have both rotational and translational capabilities. As such, the combination of substrate support 1002 movement, PVD assembly 1008a-1008c movement, and aperture 1012 movement allows processing of various site-isolated regions on a substrate 1001. Advantageously, the process parameters amongst the various site-isolated regions on the substrate 1001 can be varied in a combinatorial manner.

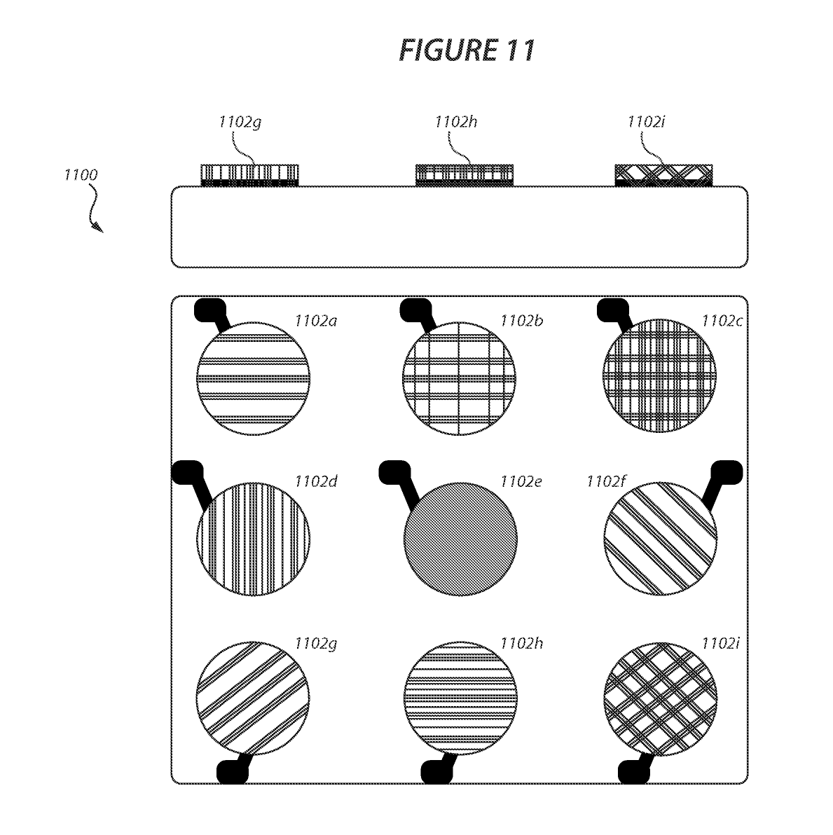

FIG. 11 is a simplified schematic diagram illustrating a substrate 1101 that has been processed in a combinatorial manner. Although the substrate 1101 in FIG. 11 is illustrated as having a square shape, one having ordinary skill in the art will understand that substrate 1101 may have any useful shape such as round, rectangular, etc.

Further, a substrate 1101 is shown having nine site-isolated regions, 1102a-1102i, illustrated thereon. The upper portion of FIG. 11 illustrates a cross-sectional view taken through the three site-isolated regions, 1102g-1102i, whereas the lower portion of FIG. 11 illustrates a top down view. The shading of the nine site-isolated regions illustrates that the process parameters used to process these regions have been varied in a combinatorial manner. The substrate 1101 may be subsequently processed in a conventional or combinatorial manner as discussed earlier with respect to FIG. 2.

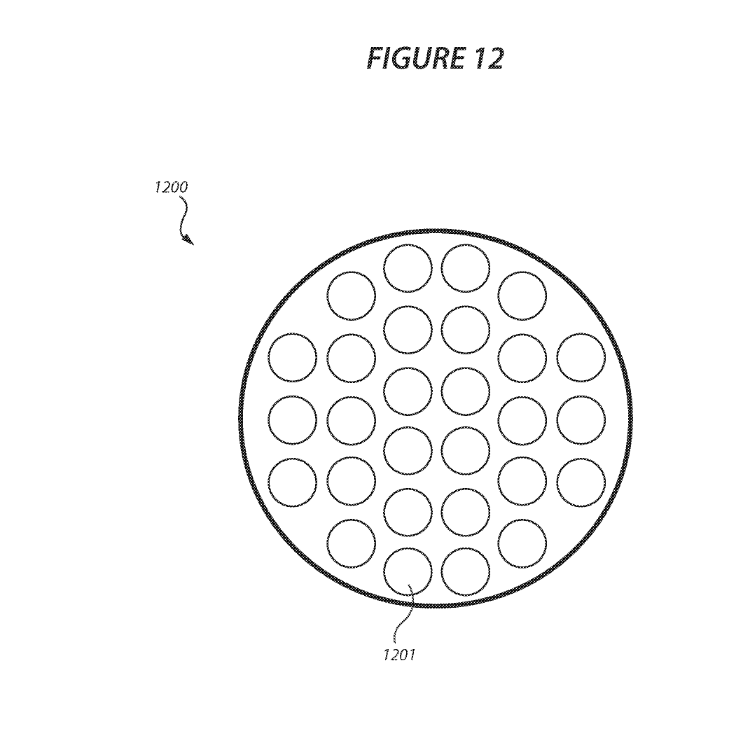

FIG. 12 is a simplified schematic diagram illustrating another example of a substrate 1200 having a pattern of site-isolated regions 1201. As shown, substrate 1200 has twenty-eight site-isolated regions 1201 which all may be processed yielding twenty-eight site-isolated regions 1201 on the substrate 1200. As such, in this example, twenty-eight independent experiments may be performed on a single substrate 1200.

Substrate 1200 may be a wafer having a diameter, such as 300 mm. In some embodiments, substrate 1200 may have other shapes, such as square or rectangular. It should be understood that substrate 1200 may be a blanket substrate (i.e., having a substantial uniform surface), a coupon (e.g., partial wafer), or even a patterned substrate having predefined regions, such as site-isolated regions 1201.

In addition, each site-isolated region 1201 may also have a certain shape, such as circular, rectangular, elliptical, or wedge-shaped such that each site-isolated region 1201 has a unique shape. A site-isolated region 1201 may be, for example, a test structure, single die, multiple die, portion of a die, other defined portion of the substrate 1200, or an undefined area of the substrate 1200 that may be subsequently defined through processing.

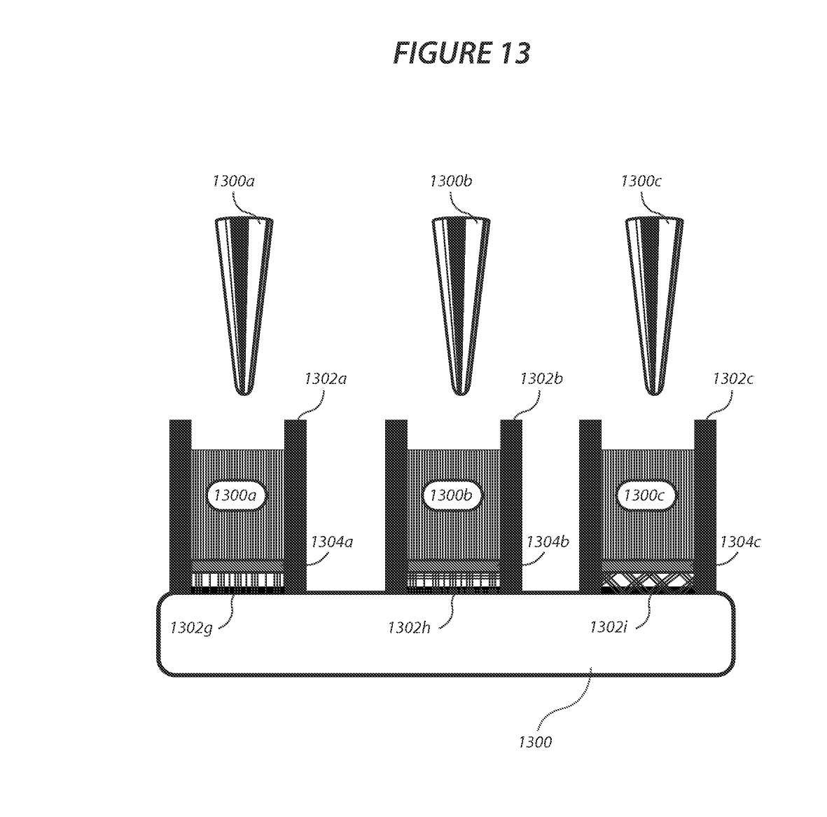

FIG. 13 is a simplified schematic diagram illustrating a combinatorial wet processing system according to some embodiments described herein. In the same manner that the combinatorial PVD system may be used to investigate materials deposited by PVD, a combinatorial wet system may be used to investigate materials deposited by solution-based techniques. An example of a combinatorial wet system is described in U.S. Pat. No. 7,544,574 which is herein incorporated by reference for all purposes.

One having ordinary skill in the art may realize that this is only one possible configuration of a combinatorial wet system. FIG. 13 illustrates a cross-sectional view of substrate 1300 taken through the three site-isolated regions 1302g-1302i similar to the upper portion of FIG. 11. As shown, solution dispensing nozzles, 1300a-1300c, supply an unique solution chemistry, 1306a-1306c, to chemically process cells 1302a-1302c. Furthermore, the figure illustrates the deposition of layers 1304a-1304c on respective site-isolated regions on the substrate 1300. Advantageously, the solution-based treatment can be customized for each of the site-isolated regions. Although FIG. 13 illustrates a deposition step, other solution-based processes such as cleaning, etching, surface treatment, surface functionalization, etc. may be investigated in a combinatorial manner.

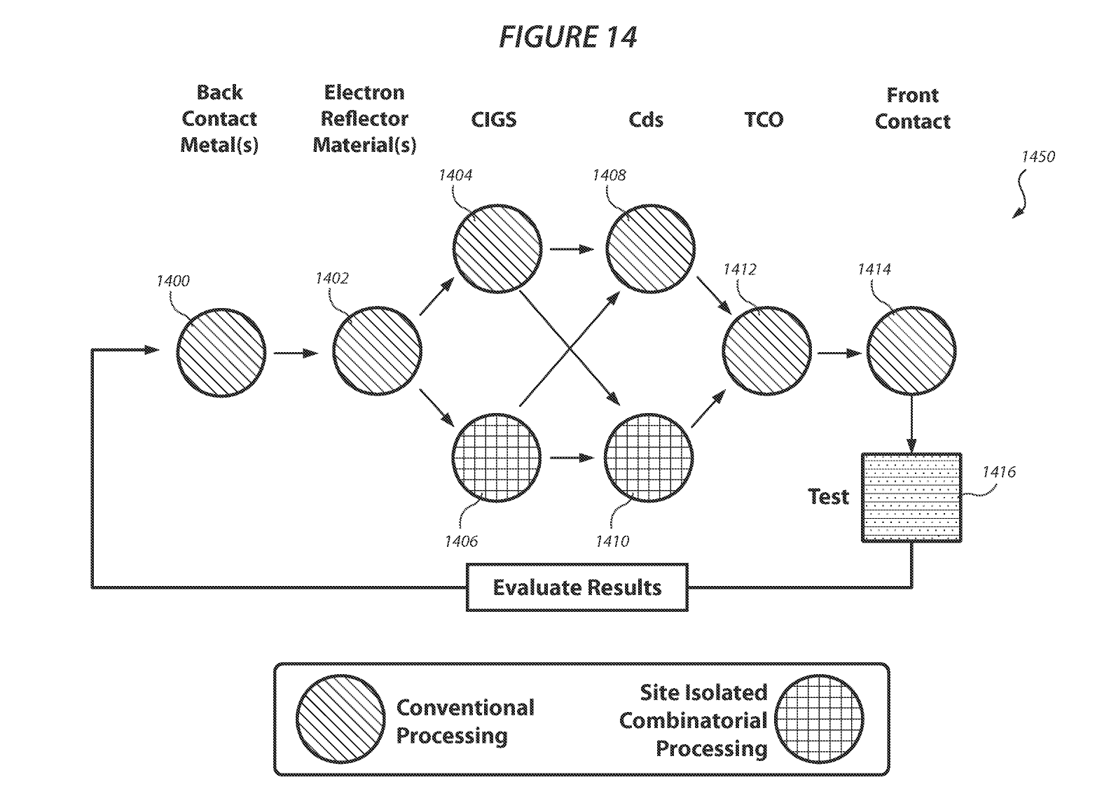

FIG. 14 is a simplified schematic diagram illustrating a method 1450 having a number of trajectories through a process sequence having both conventional and combinatorial processes to form a TFPV solar cell. It should be understood that the process represented in FIG. 14 are not exhaustive and that more or less processes may be added or subtracted therefrom.

As shown, method 1450 illustrates that a back contact and an electron reflector material(s) layer (e.g. MoSe₂ layer) may be formed in a conventional processing manner 1400, 1402 since these layers are well characterized for CIGS TFPV solar cell devices. However, method 1450 illustrates that a CIGS absorber material(s) layer may be formed in a conventional processing manner 1404 or in a site-isolated combinatorial processing manner 1406.

Next, a buffer material(s) layer (e.g. CdS) may be formed in a conventional processing manner 1408 or in a site-isolated combinatorial processing manner 1410. Further, a TCO material(s) layer may be formed in a conventional processing manner 1412 since the TCO material(s) layer is well characterized for CIGS TFPV solar cell devices. Finally, method 1450 shows a front contact layer may be formed in a conventional processing manner 1414.

After depositing the various aforementioned layers and after any subsequent processing, the various devices represented by each site-isolated region may be tested 1416. After testing 1416, the results may be evaluated.

Advantageously, the evaluated results may form the basis for additional cycles of investigation through HPC techniques to identify materials and process conditions that increase the efficiency of the CIGS TFPV device.

Table 1 lists possible trajectories through the process sequence:

TABLE 1

| Back | Electron | CIGS | Buffer | | |
|---|---|---|---|---|---|
| Contact | Reflector | Absorber | Mate- | Transparent | Front |
| Metal | Material(s) | Material(s) | rial(s) | Conductive | Contact |
| Layer | Layer | Layer | Layer | Oxide Layer | Layer |
| 1400 | 1402 | 1404 | 1408 | 1412 | 1414 |
| 1400 | 1402 | 1404 | 1410 | 1412 | 1414 |
| 1400 | 1402 | 1406 | 1408 | 1412 | 1414 |
| 1400 | 1402 | 1406 | 1410 | 1412 | 1414 |

As such, method 1450 illustrates possible trajectories through the process sequence which encompass all of the possible conventional and combinatorial processing combinations. As more variable process steps are included, the total number of required experiments may increase dramatically. As such, HPC techniques are advantageous because they limit the number of substrates to a manageable number and minimize the cost of research and development.

Methods and apparatuses for combinatorial processing have been described. It will be understood that the descriptions of some embodiments of the present disclosure do not limit the various alternative, modified and equivalent embodiments which may be included within the spirit and scope of the present disclosure as defined by the appended claims. Furthermore, in the detailed description above, numerous specific details are set forth to provide an understanding of various embodiments of the present disclosure. However, some embodiments of the present disclosure may be practiced without these specific details.

What is claimed is:

1. A solar cell, comprising:
a first metal layer disposed on a substrate;
a material layer formed above the first metal layer, the material layer operable as an electron reflector layer;
an absorber material layer formed above the material layer;
a buffer material layer formed above to the absorber material layer;
a transparent conductive oxide material layer formed above the buffer material layer; and
a second metal layer formed above the transparent conductive oxide material layer.

2. The solar cell of claim 1, wherein the absorber material layer includes at least one of a CIGS material or a CdTe material.

3. The solar cell of claim 1, wherein the material layer is p⁺-type.

4. The solar cell of claim 1, wherein the buffer material layer is n⁺-type.

5. The solar cell of claim 1, wherein the substrate comprises soda lime glass.

6. The solar cell of claim 1, wherein the material layer comprises at least one of MoSe₂, MoS₂, ZnSnO₃, MoOₓ, ZnTe, CuₓTe, MoTe, or Sb₂Te₃.

7. The solar cell of claim 1, wherein the back contact metal layer comprises at least one of molybdenum, platinum, or gold.

8. The solar cell of claim 1, wherein the transparent conductive oxide material comprises at least one of ZnO or SnO₂F.

9. The solar cell of claim 1, wherein the second metal layer comprises aluminum and nickel.

10. The solar cell of claim 1, wherein the material layer has a wider band gap than the absorber material layer.

11. The solar cell of claim 1, wherein the material layer has an energy band gap in the range of 0.3 to 0.7 electron volts higher than the energy band gap of the absorber material layer.

12. The solar cell of claim 1, wherein the absorber materials layer is an ungraded material.

13. The solar cell of claim 1, wherein the material has an energy band gap height of approximately 1.4 electron volts.

14. The solar cell of claim 1, wherein an ohmic contact is present at an interface between the material layer and the first metal layer.

15. The solar cell of claim 1 further comprising an antireflection coating layer between the second metal layer and the transparent conductive oxide material layer.

16. A method of creating a thin film photovoltaic solar cell, comprising:
forming a first metal layer above a substrate;
forming a material layer above the first metal layer, the material layer operable as an electron reflector layer;
forming an absorber material layer above the material layer;
forming an transparent conductive oxide materials above the buffer material layer; and
forming a second metal layer above the transparent conductive oxide material layer.

17. The method of claim 16, wherein the material is formed by a selenization process.

18. The method of claim 17, wherein the selenization process includes exposing the absorber material layer to at least one of H₂Se, Se vapor, or diethylselenide.

19. The method of claim 16 further comprising doping the material such that an acceptor concentration within the material layer is less than or equal to 1E18 cm⁻³.

20. A solar cell, comprising:
a first metal layer disposed on a substrate;
a material layer formed above the first metal layer, wherein the material layer comprises at least one of MoSe₂, MoS₂, ZnSnO₃, MoOₓ, ZnTe, CuₓTe, MoTe, or Sb₂Te₃;
an absorber material layer formed above the material layer;
a buffer material layer formed above to the absorber material layer;
a transparent conductive oxide material layer formed above the buffer material layer; and
a second metal layer formed above the transparent conductive oxide material layer.
